(19) United States
(12) Patent Application Publication
(10) Pub. No.: US 2020/0226309 A1
(43) Pub. Date: Jul. 16, 2020

(54) DYNAMIC RESPONSE ANALYSIS METHOD BASED ON DUAL-MODE EQUATION IN RANDOM NOISE ENVIRONMENT

(71) Applicant: SOUTHEAST UNIVERSITY, Nanjing (CN)

(72) Inventors: Yanbin LI, Nanjing (CN); Peng ZHANG, Nanjing (CN); Qingguo FEI, Nanjing (CN); Shaoqing WU, Nanjing (CN); Xuan YANG, Nanjing (CN); Dong JIANG, Nanjing (CN)

(73) Assignee: SOUTHEAST UNIVERSITY, Nanjing (CN)

(21) Appl. No.: 16/647,516

(22) PCT Filed: Apr. 18, 2018
(86) PCT No.: PCT/CN2018/083484

§ 371 Date: Mar. 15, 2020

(30) Foreign Application Priority Data
Oct. 16, 2017 (CN) 201710958872.2

(51) Int. Cl. G06F 30/23; G01H 17/00; G06F 17/16

(52) U.S. Cl. CPC G06F 30/23; G06F 17/16; G01H 17/00

(57) ABSTRACT

A dynamic response analysis method based on a dual-mode equation in a random noise environment includes the following steps: (1) dividing a structure and an acoustic cavity in an acoustic-structural coupling system into different subsystems; (2) calculating modes of the structural subsystems and the acoustic cavity subsystems; (3) calculating inter-mode coupling parameters in adjacent subsystems; (4) establishing a dual-mode equation of the coupling system; (5) by means of pre-processing, obtaining a cross power spectrum of generalized force loads applied on the subsystem modes under the action of a random load; (6) calculating the dual-mode equation to obtain cross power spectra of all participation factors of all modes; and (7) by means of modal superposition, calculating a random acoustic-structural coupling response of the system.

### CROSS REFERENCE TO THE RELATED APPLICATIONS

This application is the national phase entry of International Application No. PCT/CN2018/083484, filed on Apr. 18, 2018, which is based upon and claims priority to Chinese Patent Application No. 201710958872.2, filed on Oct. 16, 2017, the entire contents of which are incorporated herein by reference.

### TECHNICAL FIELD

The present invention relates to the technical field of acoustic-structural coupling response prediction, and in particular to a dynamic response analysis method based on a dual-mode equation in a random noise environment.

### BACKGROUND

As the spacecrafts develop to high flight speeds, they face severe random noise and other environments during the task cycle, which may cause structural failure or failure of precision instruments and meters. Therefore, the impact of random noise needs to be considered in the design process of spacecrafts. Experimental, theoretical, and numerical methods can be used to predict the dynamic response of the system under random noise excitation. Among them, the experimental method can get reliable results, but the cost of conducting experimental analysis is high and the design cycle is long; the theoretical method is only suitable for simple systems, which is difficult to solve the problem of dynamic response prediction of complex systems; and the numerical method has a good applicability for complex systems, which is an effective auxiliary means for experimental analysis. The dual-mode equation theory uses an imaginary interface to divide a system into coupled subsystems, and calculates the modes of the subsystems based on finite elements, instead of calculating the modes of the entire coupled system. Therefore, the dual-mode equation method has higher analysis efficiency than the traditional finite element method.

When the dynamic response of the system is predicted under random noise excitation based on the dual-mode equation theory, it is necessary to intercept the subsystem natural modes within a limited frequency range to participate in the response prediction. Too few selected natural modes may cause errors and too many selected natural modes may cause waste of computing resources. Therefore, a criterion is needed to define the frequency range of natural modal interception to reasonably predict the acoustic-structural coupling response of the system under random noise excitation based on the dual-mode equation.

### SUMMARY

Objective of the invention: in order to solve the technical problems in the existing dynamic response analysis technology, a criterion is provided to define the frequency range of modal interception, so as to reasonably predict the acoustic-structural coupling response of the system under random noise excitation based on a dual-mode equation, and the present invention provides a dynamic response analysis method based on a dual-mode equation in a random noise environment.

Technical solution: in order to achieve the above technical effects, the technical solution proposed by the present invention is as follows.

A dynamic response analysis method based on a dual-mode equation in a random noise environment includes the following steps:

(1) dividing a structure and an acoustic cavity in an acoustic-structural coupling system into subsystems that are continuously coupled on a coupling interface, wherein, two adjacent subsystems on the coupling interface are an acoustic cavity subsystem and a structural subsystem, respectively;

(2) setting a cutoff frequency to be equal to or greater than 1.25 times of an upper limit of an analysis frequency, and intercepting modes in the structural subsystem and the acoustic cavity subsystem, wherein natural frequencies of the modes are less than the cutoff frequency;

(3) calculating natural modal parameters of each intercepted mode based on a finite element method, wherein, the modal parameters includes modal mass, damping loss coefficient and mode shape;

(4) calculating coupling parameters between the modes intercepted in adjacent subsystems according to the modal parameters;

(5) establishing a dual-mode equation of two adjacent subsystems coupled with each other according to the modal parameters of each subsystem and the coupling parameter between the adjacent subsystems as:

$$\{ \begin{matrix}{M}_{m} ( {ω}_{m}^{2} + i ω {η}_{m} - {ω}^{2} ) {φ}_{m} ( ω ) + i ω {\sum }_{p} {W}_{mp} {ψ}_{p} ( ω ) = {F}_{m} ( ω ) , & \\ ∀ m ∈ [ 1 , … , ∞ ] \text{;} & \\ {M}_{n} ( {ω}_{n}^{2} + i ω {η}_{n} - {ω}^{2} ) {ψ}_{n} ( ω ) - i ω {\sum }_{q} {W}_{qn} {φ}_{q} ( ω ) = {F}_{n} ( ω ) , & \\ ∀ n ∈ [ 1 , … , ∞ ] \text{;} & \\ & \end{matrix}$$

wherein, ω is an angular frequency, i represents an imaginary part of an imaginary number; Mₘ is a modal mass of an m^{th} order displacement mode of the structural subsystem; ωₘ is a natural frequency of the m^{th} order displacement mode of the structural subsystem; ηₘ is a damping loss coefficient of the m^{th} order displacement mode of the structural subsystem; ϕₘ (w) is a participation factor of the m^{th} order displacement mode of the structural subsystem; Wₘₚ is a coupling parameter between the m^{th} order displacement mode of the structural subsystem and a p^{th} order sound pressure mode of the acoustic cavity subsystem; ψₚ(ω)=φₚ(ω)/iω, φₚ(ω) is a participation factor of the p^{th} order sound pressure mode of the acoustic cavity subsystem; Fₘ(ω) is a generalized force load applied on the m^{th} order displacement mode of the structural subsystem;

Mₙ is a modal mass of an n^{th} order sound pressure mode of the acoustic cavity subsystem; ωₙ is a natural frequency of the n^{th} order sound pressure mode of the acoustic cavity subsystem; ηₙ is a damping loss coefficient of the n^{th} order sound pressure mode of the acoustic cavity subsystem; ψₙ(ω)=φₙ(ω)/iω, φₙ(ω) is a participation factor of the n^{th} order sound pressure mode of the acoustic cavity subsystem; W_{qn} is a coupling parameter between a q^{th} order displacement mode of the structural subsystem and the n^{th} sound pressure mode of the acoustic cavity subsystem; φₙ(ω) is a participation factor of the q^{th} order displacement mode of the structural subsystem; Fₙ(ω) is a generalized force load applied on the n^{th} order sound pressure mode of the acoustic cavity subsystem;

(6) converting the dual-mode equation into a block matrix form:

S₁₁=X₁X₁^{H}=H_{1F}S_{FF}H_{1F}^{H},S₂₂=Y₂Y₂^{H}=H_{2F}S_{FF}H_{2F}^{H}

wherein:

$${X}_{1} = [ \begin{matrix}⋮ \\ {φ}_{m} ( ω ) \\ ⋮\end{matrix} ] , {Y}_{2} = [ \begin{matrix}⋮ \\ {ψ}_{n} ( ω ) \\ ⋮\end{matrix} ] , {F}_{1} = [ \begin{matrix}⋮ \\ {F}_{m} ( ω ) \\ ⋮\end{matrix} ] , {F}_{2} = [ \begin{matrix}⋮ \\ {F}_{n} ( ω ) \\ ⋮\end{matrix} ]$$

$${H}_{1 F} = [ \begin{matrix}{H}_{11} & {H}_{12} ] , {H}_{2 F} = [ {H}_{21} & {H}_{22} ] , {S}_{FF} = [ \begin{matrix}{F}_{1} \\ {F}_{2}\end{matrix} ] [ {F}_{1}^{H} & {F}_{2}^{H} ]\end{matrix}$$

wherein, a superscript “−1” represents an inverse matrix of a matrix, and a superscript “T” represents a transpose of a matrix; Hᵢⱼ is a transfer function matrix, i=1, 2, j=1, 2; a matrix element Hᵢⱼ(k,l) represents a participation factor of a k^{th} order mode in an i^{th} subsystem when a unit generalized force acts on an l^{th} order mode in a j^{th} subsystem; and the transfer function matrix is calculated by a formula as follows:

$$[ \begin{matrix}{H}_{11} & {H}_{12} \\ {H}_{21} & {H}_{22}\end{matrix} ] = {[ \begin{matrix}{R}_{11} & j ω W \\ - j ω {W}^{T} & {R}_{22}\end{matrix} ]}^{- 1}$$

$${R}_{11} = diag [ {M}_{m} ( {ω}_{m}^{2} + i ω {η}_{m} - {ω}^{2} ) ]$$

$${R}_{22} = diag [ {M}_{n} ( {ω}_{n}^{2} + i ω {η}_{n} - {ω}^{2} ) ]$$

$$W ( m , n ) = {W}_{mn}$$

wherein, diag( ) represents a diagonal matrix, and elements in parentheses are diagonal matrix elements; W(m, n) represents an element in an m^{th} row and an n^{th} column of a matrix W, namely, a coupling parameter Wₘₙ between the m^{th} order displacement mode of the structural subsystem and the n^{th} order sound pressure mode of the acoustic cavity subsystem;

(7) calculating the acoustic-structural coupling system when only the structure is excited by a noise, wherein the block matrices S₁₁ and S₂₂ satisfy the following form:

S₁₁=H₁₁S_{F}_{₁}_{F}_{₁}H₁₁^{H},S₂₂=H₂₁S_{F}_{₁}_{F}_{₁}H₂₁^{H}

wherein, S_{F}_{₁}_{F}_{₁} is a modal load cross power spectrum matrix of the structural subsystem, an element in a k^{th} row and an l^{th} column of the S_{F}_{₁}_{F}_{₁} is Sₖₗ(ω), and Sₖₗ(ω) represents a cross power spectrum between a generalized force applied on a k^{th} order displacement mode of the structural subsystem and a generalized force load applied on an l^{th} order displacement mode of the structural subsystem when only the structural subsystem is excited by a random noise, and Sₖₗ(ω) is calculated by a formula as follows:

Sₖₗ(ω)=∫_{A}_{ₚ}∫_{A}_{ₚ}\tilde{W}ₖ(s₁)\tilde{W}ₗ(s₂)Sₚₚ(s₁,s₂,ω)ds₁ds₂

wherein, Aₚ is an acting surface of a surface pressure load, \tilde{W}ₖ is a mode shape of the k^{th} order displacement mode of the structural subsystem, \tilde{W}ₗ is a mode shape of the l^{th} order displacement mode of the structural subsystem, Sₚₚ(s₁, s₂, ω) is a power spectrum of the surface pressure load, and s₁ and s₂ are spatial positions on the acting surface Aₚ of the surface pressure load; and

(8) calculating a displacement response of each structural subsystem and a sound pressure response of each acoustic cavity subsystem, wherein the displacement response of the structural subsystem is calculated by a formula as follows:

S_{w}(s,ω)=Ŵ₁H₁₁S_{F}_{₁}_{F}_{₁}H₁₁^{H}\tilde{W}₁^{T}

\tilde{W}₁=[ . . . \tilde{W}ₘ(s) . . . ]

S_{w}(s, ω) represents a displacement response of a w^{th} structural subsystem at an angular frequency ω at a position s;

the sound pressure response of the acoustic cavity subsystem is calculated by a formula as follows:

Sₚ(s,ω)=ω²\tilde{p}₂H₂₁S_{F}_{₁}_{F}_{₁}H₂₁^{T}\tilde{p}₂^{T}

\tilde{p}₂=[ . . . \tilde{p}ₙ(s) . . . ]

wherein, Sₚ(s, ω) represents a sound pressure response of a p^{th} acoustic cavity subsystem at the angular frequency ω at the position s.

Further, the coupling parameter is calculated by a formula as follows:

Wₘₙ=∫_{A}_{_{c}}\tilde{W}ₘ(s)\tilde{p}ₙ(s)ds

wherein, Wₘₙ is the coupling parameter between the m^{th} order displacement mode of the structural subsystem and the n^{th} order sound pressure mode of the acoustic cavity subsystem, \tilde{W}ₘ(s) is a mode shape of the m^{th} order displacement mode of the structural subsystem, \tilde{p}ₙ(s) is a mode shape of the n^{th} order sound pressure mode of the acoustic cavity subsystem, A_{c} is a coupling interface between the structural subsystem and the acoustic cavity subsystem, and s is a spatial position.

Beneficial effects: compared with the prior art, the present invention has the following advantages.

The present invention is a dynamic response prediction method under random noise excitation, which is superior to the traditional finite element method, and the method can effectively improve the dynamic response prediction efficiency of a structure under random noise excitation, shorten the design cycle, and save design costs.

### BRIEF DESCRIPTION OF THE DRAWINGS

FIG. 1 is a logical procedure diagram of the present invention;

FIG. 2 is a finite element model of a flat plate-acoustic cavity coupling system;

FIG. 3 is an acceleration response power spectrum at each response point in a stiffened panel under random noise excitation; and

FIG. 4 is an sound pressure response power spectrum at each response point in an acoustic cavity under random noise excitation.

### DETAILED DESCRIPTION OF THE EMBODIMENTS

The present invention is further described below with reference to the drawings.

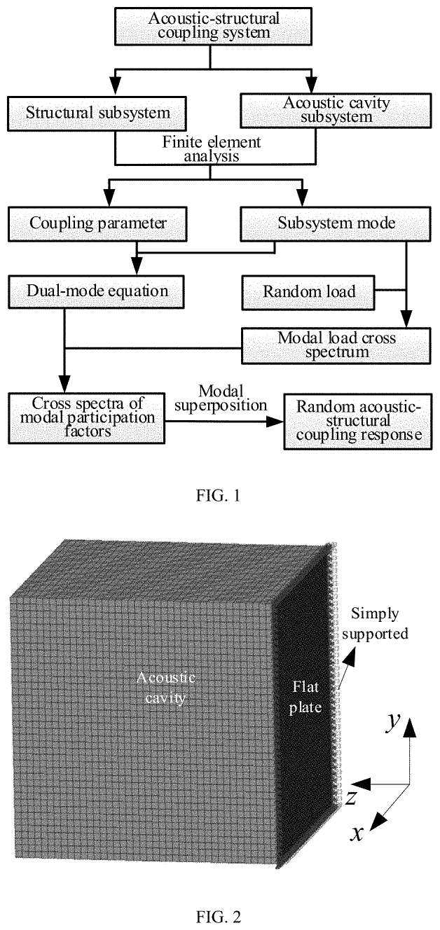

FIG. 1 is a logical procedure diagram of the present invention, and the present invention includes the following steps.

Step (1): a structure and an acoustic cavity in an acoustic-structural coupling system are divided into different subsystems; the acoustic-structural coupling system is a structural-acoustic cavity coupling system, wherein the structural vibration has an interaction with the sound pressure pulsation; and boundary conditions on an coupling interface of the subsystems are approximated, wherein, a boundary condition on the coupling interface of a structural subsystem are approximated as a free state, and a boundary condition on the coupling interface of a acoustic cavity subsystem are approximated as a fixed boundary.

Step (2): modes of the structural subsystem and the acoustic cavity subsystem are calculated, wherein the natural frequencies of the modes are lower than 1.25 times of an upper limit of an analysis band; and specifically, modal parameters of the structural subsystem and the acoustic cavity subsystem are calculated based on a finite element method.

Step (3): coupling parameters between the modes in adjacent subsystems are calculated, wherein the natural frequencies of the modes are lower than 1.25 times of the upper limit of the analysis band; and specifically, the coupling parameter is calculated by the following formula:

Wₘₙ=∫_{A}_{_{c}}\tilde{W}ₘ(s)\tilde{p}ₙ(s)ds (1)

wherein, Wₘₙ is a coupling parameter between an m^{th} order displacement mode of the structural subsystem and an n^{th} order sound pressure mode of the acoustic cavity subsystem, \tilde{W}ₘ(s) is a mode shape of the m^{th} order displacement mode of the structural subsystem, \tilde{p}ₙ(s) is a mode shape of the n^{th} order sound pressure mode of the acoustic cavity subsystem, A_{c} is a coupling interface between the structural subsystem and the acoustic cavity subsystem, and s is a spatial position.

Step (4): a dual-mode equation of the adjacent coupling subsystem is established;

$$\{ \begin{matrix}{M}_{m} ( {ω}_{m}^{2} + i ω {η}_{m} - {ω}^{2} ) {φ}_{m} ( ω ) + i ω {\sum }_{p} {W}_{mp} {ψ}_{p} ( ω ) = {F}_{m} ( ω ) , & \\ ∀ m ∈ [ 1 , … , ∞ ] \text{;} & \\ {M}_{n} ( {ω}_{n}^{2} + i ω {η}_{n} - {ω}^{2} ) {ψ}_{n} ( ω ) - i ω {\sum }_{q} {W}_{qn} {φ}_{q} ( ω ) = {F}_{n} ( ω ) , & \\ ∀ n ∈ [ 1 , … , ∞ ] \text{;} & \end{matrix} \qquad ( 2 )$$

wherein, ω is an angular frequency, i represents an imaginary part of an imaginary number; Mₘ is a modal mass of the m^{th} order displacement mode of the structural subsystem; ωₘ is a natural frequency of the m^{th} order displacement mode of the structural subsystem; ηₘ is a damping loss coefficient of the m^{th} order displacement mode of the structural subsystem; φₘ (ω) is a participation factor of the m^{th} order displacement mode of the structural subsystem; Wₘₚ is a coupling parameter between the m^{th} order displacement mode of the structural subsystem and a p^{th} order sound pressure mode of the acoustic cavity subsystem; ψₚ(ω)=φₚ(ω)/iω, φₚ(ω) is a participation factor of the p^{th} order sound pressure mode of the acoustic cavity subsystem; Fₘ(ω) is a generalized force load applied on the m^{th} order displacement mode of the structural subsystem; Mₙ is a modal mass of an n^{th} order sound pressure mode of the acoustic cavity subsystem; ωₙ is a natural frequency of the n^{th} order sound pressure mode of the acoustic cavity subsystem; ηₙ is a damping loss coefficient of the n^{th} order sound pressure mode of the acoustic cavity subsystem; ψₙ(ω)=φₙ(ω)/iω, φₙ(ω) is a participation factor of the n^{th} order sound pressure mode of the acoustic cavity subsystem; W_{qn} is a coupling parameter between a q^{th} order displacement mode of the structural subsystem and the n^{th} sound pressure mode of the acoustic cavity subsystem; φ_{q}(ω) is a participation factor of the q^{th} order displacement mode of the structural subsystem; and Fₙ(ω) is a generalized force load applied on the n^{th} order sound pressure mode of the acoustic cavity subsystem.

Step (5): by means of pre-processing, a cross power spectrum of generalized force loads applied on the subsystem modes under the action of a random load is obtained, and specifically is as follows:

when the structural subsystem is excited by a random noise, a cross power spectrum between a generalized force applied on a k^{th} order displacement mode of the structural subsystem and a generalized force load applied on an l^{th} order displacement mode of the structural subsystem is:

Sₖₗ(ω)=∫_{A}_{ₚ}∫_{A}_{ₚ}\tilde{W}ₖ(s₁)\tilde{W}ₗ(s₂)Sₚₚ(s₁,s₂,ω)ds₁ds₂ (3)

wherein, Aₚ is an acting surface of a surface pressure load, \tilde{W}ₖ is a mode shape of the k^{th} order displacement mode of the structural subsystem, \tilde{W}ₗ is a mode shape of the l^{th} order displacement mode of the structural subsystem, Sₚₚ(s₁, s₂, ω) is a power spectrum of the surface pressure load, and s₁ and s₂ are spatial positions.

Step (6): the dual-mode equation is calculated to obtain cross power spectra of all participation factors of all modes; and the steps are as follows:

the dual-mode equation of the system is written in a form of a block matrix, and the cross power spectra of modal participation factors of the subsystems are calculated based on the following formulas:

S₁₁=X₁X₁^{H}=H_{1F}S_{FF}H_{1F}^{H},S₂₂=Y₂Y₂^{H}=H_{2F}S_{FF}H_{2F}^{H} (4)

wherein, a superscript “H” represents conjugate transpose;

$$\begin{matrix}{H}_{1 F} = [ \begin{matrix}{H}_{11} & {H}_{12} ] , {H}_{2 F} = [ {H}_{21} & {H}_{22} ] , {S}_{FF} = [ \begin{matrix}{F}_{1} \\ {F}_{2}\end{matrix} ] [ {F}_{1}^{H} & {F}_{2}^{H} ]\end{matrix} & ( 5 ) \\ {X}_{1} = [ \begin{matrix}⋮ \\ {φ}_{m} ( ω ) \\ ⋮\end{matrix} ] , {Y}_{2} = [ \begin{matrix}⋮ \\ {ψ}_{n} ( ω ) \\ ⋮\end{matrix} ] , {F}_{1} = [ \begin{matrix}⋮ \\ {F}_{m} ( ω ) \\ ⋮\end{matrix} ] , {F}_{2} = [ \begin{matrix}⋮ \\ {F}_{n} ( ω ) \\ ⋮\end{matrix} ] & ( 6 )\end{matrix}$$

wherein, Hᵢⱼ is a transfer function matrix (i=1, 2; j=1, 2), the meaning of a matrix element Hᵢⱼ(k,l) is: a participation factor of a k^{th} order mode in an i^{th} subsystem when a unit generalized force acts on an l^{th} mode in a j^{th} subsystem. The transfer function matrix can be obtained from the following formula:

$$[ \begin{matrix}{H}_{11} & {H}_{12} \\ {H}_{21} & {H}_{22}\end{matrix} ] = {[ \begin{matrix}{R}_{11} & j ω W \\ - j ω {W}^{T} & {R}_{22}\end{matrix} ]}^{- 1} \qquad ( 7 )$$

wherein, a superscript “−1” represents the inverse of the matrix, and a superscript “T” represents the transpose of the matrix.

R₁₁=diag[Mₘ(ωₘ²+iωηₘ−ω²)] (8)

R₂₂=diag[Mₙ(ωₙ²+iωηₙ−ω²)] (9)

W(m,n)=Wₘₙ (10)

wherein, diag( ) represents a diagonal matrix, and the elements in parentheses are diagonal matrix elements. When only the structure is excited by noise, the cross power spectra of modal participation factors of the subsystems are:

S₁₁=H₁₁S_{F}_{₁}_{F}_{₁}H₁₁^{H},S₂₂=H₂₁S_{F}_{₁}_{F}_{₁}H₂₁^{H} (11)

wherein, S_{F}_{₁}_{F}_{₁} is a modal load cross power spectrum matrix of the structural subsystem, and an element Sₘₙ(ω) of the S_{F}_{₁}_{F}_{₁} in the m^{th} row and the n^{th} column can be calculated based on formula (3).

Step (7): the random acoustic-structural coupling response of the system is calculated by means of modal superposition; and specifically, the displacement response of the structural subsystem is calculated by the following formula:

S_{w}(s,ω)=\tilde{W}₁S₁₁\tilde{W}₁^{T} (12)

wherein, \tilde{W}₁=[ . . . \tilde{W}ₘ(s) . . . ];

the sound pressure response of the acoustic cavity subsystem is calculated by the following formula:

Sₚ(s,ω)=ω²\tilde{p}₂S₂₂\tilde{p}₂^{T} (12)

wherein, \tilde{p}₂=[ . . . \tilde{p}ₙ(s) . . . ].

In the following, a flat plate-acoustic cavity coupling model is taken as an example to specifically describe the technical effect of the present invention. The flat plate-acoustic cavity coupling model is as shown in FIG. 2. The boundary conditions of the flat plate are as follows: the flat plate is simply supported at four sides. The parameters of the flat plate are given in Table 1:

TABLE 1
Parameter values of the flat plate

| Parameter | Value | |
|---|---|---|
| Side length Lₓ along x axial | 1 | m |
| Side length L_{y} along y axial | 1 | m |
| Modulus of elasticity | 2 × 10¹¹ | Pa |
| Density | 7800 | kg/m³ |
| Poisson's ratio | 0.3 | |
| Thickness | 5 | mm |

| | |
|---|---|
| Damping | 0.01 |

The boundary conditions of the acoustic cavity are as follows: except for a surface coupled with the flat plate, the other surfaces are fixed boundaries. The parameters of the acoustic cavity are given in Table 2.

TABLE 2
Parameter values of the acoustic cavity

| Parameter | Value | |
|---|---|---|
| side length Lₓ along x axial | 1 | m |
| side length L_{y} along y axial | 1 | m |
| side length L_{z} along z axial | 1 | m |
| Density | 1.29 | kg/m³ |
| Speed of sound | 340 | m/s |

| | |
|---|---|
| Damping | 0.01 |

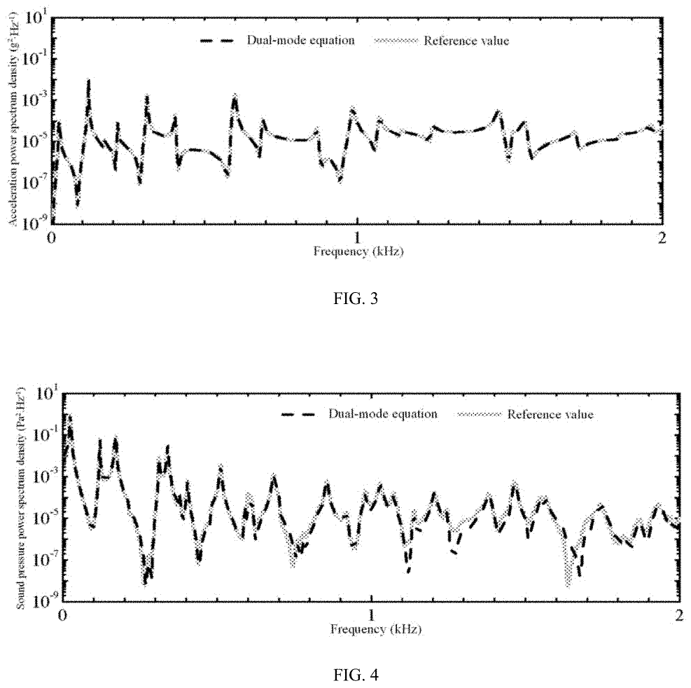

A unit random noise load is applied to an outer surface of a panel of the flat plate, and the power spectrum of the random noise load is Sₚₚ(s₁, s₂, ω)=1. After the above steps, an acceleration response power spectrum at a response point with the coordinates (0.3 m, 0.1 m) on the stiffened panel is obtained, as shown in FIG. 3; and an sound pressure response power spectrum at a response point with the coordinates (0.3 m, 0.1 m, 0 m) in the acoustic cavity is obtained, as shown in FIG. 4.

The reference values in FIGS. 3 and 4 are calculated by the direct finite element method. During the analysis of the dual-mode equation method, the flat plate mode and the acoustic cavity mode within 2.5 kHz are selected to participate in the response prediction. The results in FIGS. 3 and 4 show that the dynamic response analysis method provided by the present invention can accurately predict the dynamic response of the system under random noise excitation based on the dual-mode equation, which effectively solves the problem of dynamic response prediction under random noise excitation and improves efficiency of analysis.

The above is only a preferred embodiment of the present invention. It should be noted that an ordinary person skilled in the art can make several improvements and modifications without departing from the principles of the present invention, and these improvements and modifications shall fall within the protective scope of the present invention.

What is claimed is:

1. A dynamic response analysis method based on a dual-mode equation in a random noise environment, comprising the following steps:
(1) dividing a structure and an acoustic cavity in an acoustic-structural coupling system into a plurality of subsystems, wherein, the plurality of subsystems are continuously coupled on a coupling interface, and two adjacent subsystems on the coupling interface are an acoustic cavity subsystem and a structural subsystem, respectively;
(2) setting a cutoff frequency to be equal to or greater than 1.25 times of an upper limit of an analysis frequency, and intercepting a plurality of modes in the structural subsystem and the acoustic cavity subsystem, wherein natural frequencies of the plurality of modes are less than the cutoff frequency;
(3) calculating a plurality of modal parameters of each mode of the plurality of modes based on a finite element method, wherein, the plurality of modal parameters comprises a modal mass, a damping loss coefficient and a mode shape;
(4) calculating a coupling parameter between the plurality of modes intercepted in the acoustic cavity subsystem and the structural subsystem according to the plurality of modal parameters;
(5) establishing a dual-mode equation of the acoustic cavity subsystem and the structural subsystem according to the plurality of modal parameters and the coupling parameter as:
$$\{ \begin{matrix}{M}_{m} ( {ω}_{m}^{2} + i ω {η}_{m} - {ω}^{2} ) {φ}_{m} ( ω ) + i ω {\sum }_{p} {W}_{mp} {ψ}_{p} ( ω ) = {F}_{m} ( ω ) , & \\ ∀ m ∈ [ 1 , … , ∞ ] \text{;} & \\ {M}_{n} ( {ω}_{n}^{2} + i ω {η}_{n} - {ω}^{2} ) {ψ}_{n} ( ω ) - i ω {\sum }_{q} {W}_{qn} {φ}_{q} ( ω ) = {F}_{n} ( ω ) , & \\ ∀ n ∈ [ 1 , … , ∞ ] \text{;} & \end{matrix}$$
wherein, ω is an angular frequency, i represents an imaginary part of an imaginary number; Mₘ is a modal mass of an m^{th} order displacement mode of the structural subsystem; ωₘ is a natural frequency of the m^{th} order displacement mode of the structural subsystem; ηₘ is a damping loss coefficient of the m^{th} order displacement mode of the structural subsystem; ϕₘ(ω) is a participation factor of the m^{th} order displacement mode of the structural subsystem; Wₘₚ is a coupling parameter between the m^{th} order displacement mode of the structural subsystem and a p^{th} order sound pressure mode of the acoustic cavity subsystem; ψₚ(ω)=φₚ(ω)/iω, φₚ(ω) is a participation factor of the p^{th} order sound pressure mode of the acoustic cavity subsystem; Fₘ(ω) is a generalized force load applied on the m^{th} order displacement mode of the structural subsystem;
Mₙ is a modal mass of an n^{th} order sound pressure mode of the acoustic cavity subsystem; ωₙ is a natural frequency of the n^{th} order sound pressure mode of the acoustic cavity subsystem; ηₙ is a damping loss coefficient of the n^{th} order sound pressure mode of the acoustic cavity subsystem; ψₙ(ω)=φₙ(ω)/iω, φₙ(ω) is a participation factor of the n^{th} order sound pressure mode of the acoustic cavity subsystem; W_{qn} is a coupling parameter between a q^{th} order displacement mode of the structural subsystem and the n^{th} sound pressure mode of the acoustic cavity subsystem; ϕ_{q}(ω) is a participation factor of the q^{th} order displacement mode of the structural subsystem; Fₙ(ω) is a generalized force load applied on the n^{th} order sound pressure mode of the acoustic cavity subsystem;
(6) converting the dual-mode equation into a block matrix form:
S₁₁=X₁X₁^{H}=H_{1F}S_{FF}H_{1F}^{H},S₂₂=Y₂Y₂^{H}=H_{2F}S_{FF}H_{2F}^{H},
wherein:
$${X}_{1} = [ \begin{matrix}⋮ \\ {φ}_{m} ( ω ) \\ ⋮\end{matrix} ] , {Y}_{2} = [ \begin{matrix}⋮ \\ {ψ}_{n} ( ω ) \\ ⋮\end{matrix} ] , {F}_{1} = [ \begin{matrix}⋮ \\ {F}_{m} ( ω ) \\ ⋮\end{matrix} ] , {F}_{2} = [ \begin{matrix}⋮ \\ {F}_{n} ( ω ) \\ ⋮\end{matrix} ] , \\ {H}_{1 F} = [ \begin{matrix}{H}_{11} & {H}_{12} ] , {H}_{2 F} = [ {H}_{21} & {H}_{22} ] , {S}_{FF} = [ \begin{matrix}{F}_{1} \\ {F}_{2}\end{matrix} ] [ {F}_{1}^{H} & {F}_{2}^{H} ]\end{matrix} ,$$
wherein, a superscript “−1” represents an inverse matrix of a matrix, and a superscript “T” represents a transpose of a matrix; Hᵢⱼ is a transfer function matrix, i=1, 2, j=1, 2; a matrix element Hᵢⱼ(k,l) represents a participation factor of a k^{th} order mode in an i^{th} subsystem when a unit generalized force acts on an l^{th} order mode in a j^{th} subsystem; and the transfer function matrix is calculated by a formula as follows:
$$[ \begin{matrix}{H}_{11} & {H}_{12} \\ {H}_{21} & {H}_{22}\end{matrix} ] = {[ \begin{matrix}{R}_{11} & j ω W \\ - j ω {W}^{T} & {R}_{22}\end{matrix} ]}^{- 1} , \\ {R}_{11} = diag [ {M}_{m} ( {ω}_{m}^{2} + i ω {η}_{m} - {ω}^{2} ) ] , \\ {R}_{22} = diag [ {M}_{n} ( {ω}_{n}^{2} + i ω {η}_{n} - {ω}^{2} ) ] , \\ W ( m , n ) = {W}_{mn} ,$$
wherein, diag( ) represents a diagonal matrix, and elements in parentheses of the diag( ) are diagonal matrix elements; W(m, n) represents an element in an m^{th} row and an n^{th} column of a matrix W, and W (m,n) is a coupling parameter Wₘₙ between the m^{th} order displacement mode of the structural subsystem and the n^{th} order sound pressure mode of the acoustic cavity subsystem;
(7) calculating the acoustic-structural coupling system when only the structure is excited by a random noise, wherein the block matrices S₁₁ and S₂₂ satisfy the following form:
S₁₁=H₁₁S_{F}_{₁}_{F}_{₁}H₁₁^{H},S₂₂=H₂₁S_{F}_{₁}_{F}_{₁}H₂₁^{H},
wherein, S_{F}_{₁}_{F}_{₁} is a modal load cross power spectrum matrix of the structural subsystem, an element in a k^{th} row and an l^{th} column of the S_{F}_{₁}_{F}_{₁} is Sₖₗ(ω), and Sₖₗ(ω) represents a cross power spectrum between a generalized force applied on a k^{th} order displacement mode of the structural subsystem and a generalized force load applied on an l^{th} order displacement mode of the structural subsystem when only the structural subsystem is excited by the random noise, and Sₖₗ(ω) is calculated by a formula as follows:
Sₖₗ(ω)=∫_{A}_{ₚ}∫_{A}_{ₚ}\tilde{W}ₖ(s₁)\tilde{W}ₗ(s₂)Sₚₚ(s₁,s₂,ω)ds₁ds₂,
wherein, Aₚ is an acting surface of a surface pressure load, \tilde{W}ₖ is a mode shape of the k^{th} order displacement mode of the structural subsystem, \tilde{W}ₗ is a mode shape of the l^{th} order displacement mode of the structural subsystem, Sₚₚ(s₁, s₂, ω) is a power spectrum of the surface pressure load, and s₁ and s₂ are spatial positions on the acting surface Aₚ of the surface pressure load; and
(8) calculating a displacement response of the structural subsystem and a sound pressure response of the acoustic cavity subsystem, wherein the displacement response of the structural subsystem is calculated by a formula as follows:
S_{w}(s,ω)=Ŵ₁H₁₁S_{F}_{₁}_{F}_{₁}H₁₁^{H}\tilde{W}₁^{T},
\tilde{W}₁=[ . . . \tilde{W}ₘ(s) . . . ],
wherein, S_{w}(s, ω) represents a displacement response of a w^{th} structural subsystem at an angular frequency ω at a position s;
the sound pressure response of the acoustic cavity subsystem is calculated by a formula as follows:
Sₚ(s,ω)=ω²\tilde{p}₂H₂₁S_{F}_{₁}_{F}_{₁}H₂₁^{T}\tilde{p}₂^{T},
\tilde{p}₂=[ . . . \tilde{p}ₙ(s) . . . ],
wherein, Sₚ(s, ω) represents a sound pressure response of a p^{th} acoustic cavity subsystem at the angular frequency ω at the position s.

2. The dynamic response analysis method based on the dual-mode equation under the random noise environment according to claim 1, wherein, the coupling parameter is calculated by a formula as follows:
Wₘₙ=∫_{A}_{_{c}}\tilde{W}ₘ(s)\tilde{p}ₙ(s)ds,
wherein, Wₘₙ is a coupling parameter between the m^{th} order displacement mode of the structural subsystem and the n^{th} order sound pressure mode of the acoustic cavity subsystem, \tilde{W}ₘ(s) is a mode shape of the m^{th} order displacement mode of the structural subsystem, \tilde{p}ₙ(s) is a mode shape of the n^{th} order sound pressure mode of the acoustic cavity subsystem, A_{c} is a coupling interface between the structural subsystem and the acoustic cavity subsystem, and s is a spatial position.
